(19) United States
(12) Patent Application Publication
(10) Pub. No.: US 2011/0236806 A1
(43) Pub. Date: Sep. 29, 2011

(54) DC VOLTAGE CHARGING OF CATHODE FOR PLASMA STRIKING

(75) Inventors: ALAN HIROSHI OUYE, San Mateo, CA (US); DARIN BIVENS, San Mateo, CA (US); DAVID KNICK, Sunnyvale, CA (US)

(73) Assignee: APPLIED MATERIALS, INC., Santa Clara, CA (US)

(21) Appl. No.: 12/900,564

(22) Filed: Oct. 8, 2010

Related U.S. Application Data
(60) Provisional application No. 61/317,564, filed on Mar. 25, 2010.

(51) Int. Cl. G03F 1/00

(52) U.S. Cl. 430/5

(57) ABSTRACT

Methods for processing photomasks are provided herein. In some embodiments, a method for processing a photomask may include providing a photomask to a substrate support within a process chamber; providing a process gas to the process chamber having the photomask disposed therein; providing a negative or zero voltage to a substrate support cathode having the photomask disposed thereon; providing a source RF power to an anode coupled to the process chamber to ignite the process gas to form a plasma; and processing the photomask.

### CROSS-REFERENCE TO RELATED APPLICATIONS

This application claims benefit of U.S. provisional patent application Ser. No. 61/317,564, filed Mar. 25, 2010, which is herein incorporated by reference.

### FIELD

Embodiments of the present invention generally relate to photomask processing.

### BACKGROUND

Conventional integrated circuit fabrication involves transferring circuit patterns representing different layers of the chip onto a semiconductor substrate using a series of reusable masks, or photomasks. The photomasks typically consist of a glass or a quartz substrate having a layer of chromium disposed thereon. One or more antireflective coatings and one or more layers of photoresist are disposed above the mask to facilitate transferring the circuit pattern to the mask. In some applications, for example where the desired circuit density necessitates the use of a phase-shift mask (e.g., an embedded attenuated phase-shift mask (EAPSM) or an alternating aperture phase-shift mask (AAPSM), an additional phase shift layer, such as a molybdenum and silicon (MoSi) containing layer, may also be present.

In conventional photomask fabrication, typically the circuit pattern is first written onto the photomask by exposing portions of the photoresist to ultraviolet light, making the exposed portions soluble in a developing solution. The soluble portion of the resist is then removed, exposing the underlying layers (e.g., the chromium and/or phase shift layers). One or more plasma etch processes are then performed to etch the circuit pattern into the underlying layers.

The inventors have provided an improved method of processing photomasks.

### SUMMARY

Methods for processing photomasks are provided herein. In some embodiments, method for processing a photomask may include providing a photomask to a substrate support within a process chamber; providing a process gas to the process chamber having the photomask disposed therein; providing a negative or zero voltage to a substrate support cathode having the photomask disposed thereon; providing a source RF power to an anode coupled to the process chamber to ignite the process gas to form a plasma; and processing the photomask.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. However, the appended drawings illustrate only typical embodiments of this invention and are not limiting of its scope, for the invention may have other equally effective embodiments.

FIG. 1 depicts a schematic, cross-section view of an illustrative process chamber that may be used to process photomasks in accordance with some embodiments of the present invention.

FIG. 2 depicts a flow chart of a method for processing photomasks in accordance with some embodiments of the present invention

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for processing photomasks are provided herein. The inventors have observed that conventional etch process gases require a high amount of energy required to ionize the process gas, making it difficult to ignite the process gas to form the plasma. In situations when a process gas fails to ignite into a plasma, the photomask being processed may become irreparably damaged, causing unnecessary waste and reducing throughput. To alleviate such problems, a bias power may be applied to facilitate ignition of the plasma. However, using a bias power in may cause particle buildup on the photomask, resulting in non-uniform etching of the photomask and/or defects. Embodiments of the inventive methods disclosed herein may advantageously provide photomask processing methods that provide consistent plasma ignition, thereby reducing or eliminating the possibility of damage to the photomask that results from the failure of a plasma to ignite.

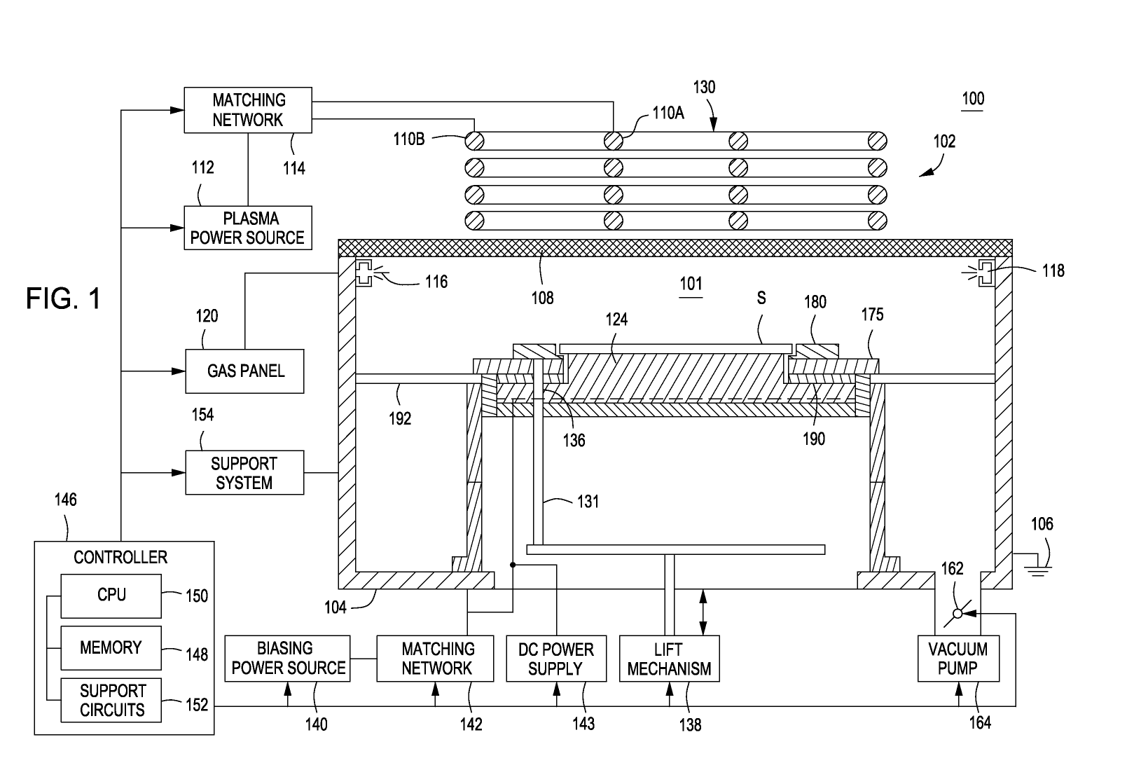

FIG. 1 depicts a schematic, cross-section view of an illustrative process chamber that may be used to process a photomask in accordance with some embodiments of the present invention. Suitable reactors that may be adapted for use with the teachings disclosed herein include, for example, the TETRA™ I, TETRA™ II and TETRA™ III Photomask etch systems, all of which are available from Applied Materials, Inc. of Santa Clara, Calif. The particular embodiment of the process chamber 100 shown herein is provided for illustrative purposes and should not be used to limit the scope of the invention.

The process chamber 100 generally comprises a processing chamber 102 having a substrate support pedestal 124, processing volume 101, and a controller 146. The processing chamber 102 includes a chamber body 104 having conductive walls that support a substantially flat dielectric ceiling 108 which is transparent to radio frequency (RF) radiation. Other embodiments of the processing chamber 102 may have other types of ceilings, e.g., a dome-shaped ceiling. Induction coils 130 which are co-axially aligned and function as an antenna are disposed above the dielectric ceiling 108 and directly above the substrate support pedestal 124 and processing volume 101. The induction coils 130 comprise an inner coil 110 A and an outer coil 110 B that are co-axial and may be selectively controlled. The induction coils 130 are coupled through a first matching network 114 to a plasma power source 112. The plasma power source 112 is typically capable of producing up to about 3000 Watts (W), or about 1500 W, at a frequency in a range from about 50 kHz to about 60 MHz, with a typical operating frequency of about 13.56 MHz. The processing chamber 102 may also include a plasma screen 192 which is utilized to confine the plasma.

The substrate support pedestal 124 (which acts as a cathode) supports a substrate “S” and, in some embodiments may be coupled to a biasing power source 140 and a DC power supply 143. The biasing power source 140 produces continuous or pulsed RF or DC power output and may be coupled to the substrate support pedestal 124 via a matching network 142. The biasing power source 140 may provide an RF signal of about 0 to about 600 W at a tunable frequency in a range from about 2 MHz to about 200 MHz, for example, 13.56 MHz. The biasing power source 140 may be configured to provide a continuous wave output or a pulsed output having a tunable pulse frequency in the range of from about 1 to about 10 kHz, with a duty cycle between about 10 to about 95 percent. Alternatively, the biasing power source 140 may produce pulsed DC power output. The DC power supply provides about 0 to about 3000 V of positive or negative voltage.

A gas panel 120 is coupled to the processing chamber 102 to provide process and/or other gases to the interior of the processing chamber 102. In the embodiment depicted in FIG. 1, the gas panel 120 is coupled to one or more gas inlets 116 formed in an annular gas channel 118 located within the sidewall of chamber body 104. It is contemplated that the one or more gas inlets 116 may be provided in other locations, for example, in the dielectric ceiling 108 of the processing chamber 102.

The pressure in the processing chamber 102 may be controlled using a throttle valve 162 and a vacuum pump 164. The vacuum pump 164 and throttle valve 162 are capable of maintaining chamber pressures in the range of about 1 to about 30 mTorr.

The temperature of the chamber body 104 may be controlled using liquid-containing conduits (not shown) that run through the walls of the chamber body 104 Wall temperature is generally maintained at about 65 degrees Celsius. Typically, the chamber body 104 is formed from a metal (e.g., aluminum, stainless steel, and the like) and is coupled to an electrical ground 106. The process chamber 100 also comprises conventional systems for process control, internal diagnostic, end point detection, and the like. Such systems are collectively shown as support systems 154.

The substrate support pedestal 124 has a central protruding portion having a shape and dimensions that substantially match those of a typical substrate, e.g., a square shaped substrate, such as a photomask. A cover ring 175 and a capture ring 180 are disposed above the substrate support pedestal 124. An annular insulator 190 is provided between an outer portion of the substrate support pedestal 124 and the cover ring 175. In some embodiments, the substrate support pedestal 124 may comprise one or more cooling channels (not shown) embedded below the surface of the substrate support pedestal 124, to allow a coolant to be flowed there through, thereby allowing a temperature of the substrate support pedestal 124 to be controlled.

The capture ring 180 is designed to be moved between two positions by a lift mechanism 138 which comprises a plurality of lift pins 131 (one lift pin is shown) that travel through respective guide holes 136. In a first position, the capture ring 180 is lowered beneath the top surface of the substrate support pedestal 124, leaving the substrate “S” supported by the substrate support pedestal 124 for processing. In this first position, the capture ring 180 essentially couples with the protruding portions (not shown) of the cover ring 175 to form a complete annular ring such that the top surfaces of the capture ring 180 and the cover ring 175 are substantially in the same horizontal plane. At least certain portions of the capture ring 180 and the cover ring 175 are complementarily shaped, in certain embodiments. After substrate processing is completed, the capture ring 180 is lifted upwards to its second position, supporting the substrate “S” for transfer out of the processing chamber 102 and is ready for receiving another substrate for processing.

In some embodiments, the substrate support pedestal 124 may comprise additional features to facilitate selective application of the power provided by the biasing power source 140 and/or the DC power supply 143. For example, the substrate support pedestal 124 may comprise one or more zones (not shown) wherein the one or more zones may be individually configured to be electrically hot or grounded.

The controller 146 comprises a central processing unit (CPU) 150, a memory 148, and support circuits 152 for the CPU 150 and facilitates control of the components of the process chamber 100 and, as such, of the etching process. The inventive method is generally stored in the memory 148 or other computer-readable medium accessible to the CPU 150 as a software routine. Alternatively, such software routine may also be stored and/or executed by a second CPU (not shown) that is remotely located from the hardware being controlled by the CPU 150.

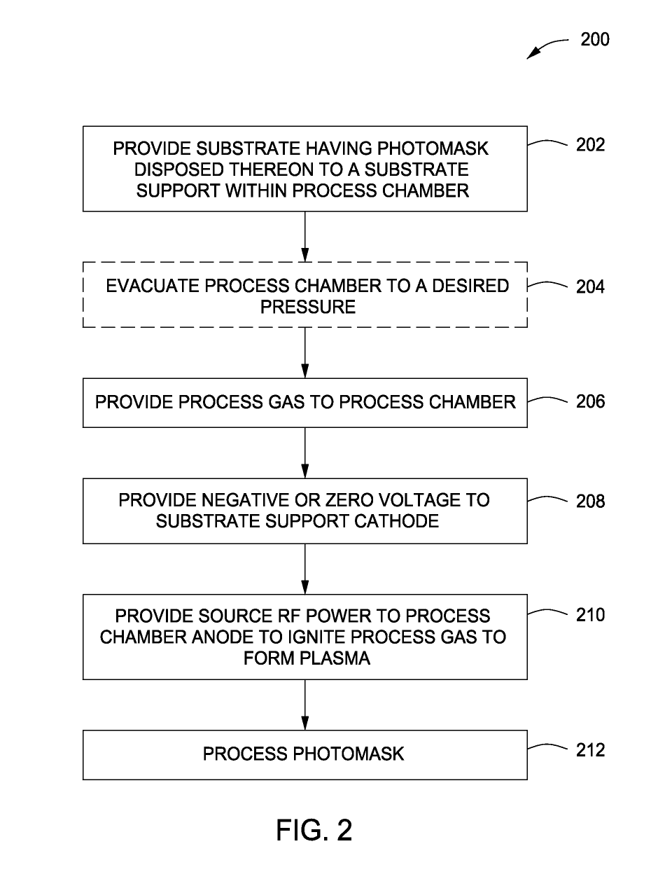

FIG. 2 depicts a flow chart of a method for processing a photomask in accordance with some embodiments of the present invention. The method 200 may be performed in any suitable process chamber configured for photomask processing, such as the TETRA™ I, TETRA™ II or TETRA™ III Photomask etch systems, all of which are available from Applied Materials, Inc. of Santa Clara, Calif., or such as the process chamber 100 described above with respect to FIG. 1.

The method 200 begins at 202 where a substrate having a photomask disposed thereon is provided to a substrate support in a process chamber. The substrate may comprise any materials suitable for photomask processing, for example, an optically transparent material, such as a glass, or a silicon containing material such as quartz (SiO₂).

The photomask may be any photomask suitable for substrate processing. For example, in some embodiments, the photomask may comprise a chromium containing layer, such as chromium, chromium oxynitride, or the like. Alternatively, or in combination, in some embodiments, the photomask may comprise additional layers. For example, in embodiments where the photomask is a phase-shift photomask, such as an embedded attenuated phase-shift mask (EAPSM) or an alternating aperture phase-shift mask (AAPSM), a phase shift layer may be included. In such embodiments, the phase shift layer may comprise a molybdenum and silicon containing layer, for example, such as molybdenum silicide (MoSi), molybdenum silicon oxynitride (MoSiON), or the like. In some embodiments, the photomask may comprise additional layers, such as photoresist layers, antireflective layers, or the like.

Next, at 204, in some embodiments, the process chamber may be optionally evacuated to a desired pressure. The process chamber may be maintained at any pressure suitable for the specific process being performed. For example, in some embodiments the process chamber may be maintained at a pressure of about 2 mTorr to about 8 mTorr, or in some embodiments, about 4 mTorr. The pressure may be maintained at a constant level, or may be adjusted throughout the process. For example, the process chamber may be evacuated to a pressure of about 4 mTorr to facilitate ignition of the process gas to form a plasma (described below with respect to 210) and then, in some embodiments raised or lowered for photomask processing (described below with respect to 212).

Next, at 206 a process gas is provided to the process chamber. In some embodiments, the process gas may be provided to the process chamber at a total flow rate of about 150 sccm to about 300 sccm. In some embodiments, the process gas may generally comprise one or more ignition gases and one or more carrier and/or dilutant gases. In some embodiments, the ignition gas may be provided at a flow rate of from about 5 to about 10 sccm. The ignition gas may be any gas suitable for processing of the particular photomask being processed. For example, in some embodiments, the ignition gas may comprise at least one of sulfur hexafluoride (SF₆), argon (Ar), nitrogen (N₂), or the like. In some embodiments, for example where the photomask comprises one or more molybdenum and silicon containing layers, the ignition gas may comprise sulfur hexafluoride (SF₆).

In some embodiments, the dilutant gas may comprise an inert gas, for example, such as nitrogen (N₂), or a noble gas such as helium (He), argon (Ar), or the like. In some embodiments, the dilutant gas may be provided at a flow rate of about 150 to about 300 sccm. In some embodiments, the flow rate ratio of the dilutant gas to the ignition gas may be about 15:1 to about 60:1, or about 30:1. In some embodiments, the dilutant gas is helium. In some embodiments, the dilutant gas is helium mixed with nitrogen or argon and the ignition gas is sulfur hexafluoride. In some embodiments, the ratio of helium mixed with nitrogen or argon to sulfur hexafluoride is about 30:1.

Next, at 206 a negative or zero voltage is provided to a substrate support cathode. In some embodiments, for example, where a negative voltage is provided to the substrate support, the negative voltage may be supplied by a high DC voltage power supply, for example, such as the high DC voltage power supply 143 described above with respect to FIG. 1. In such embodiments, the high DC voltage power supply may provide a negative voltage of up to about 3000 volts. In some embodiments, the negative voltage provided may be dependent on power conditions required by the particular process. For example, the magnitude of the voltage provided to the substrate support may be inversely related to the source RF power provided to the process chamber to ignite the process gas, as described below at 210. Providing the negative voltage to the substrate support supplies the process gas with additional ionization energy, thereby facilitating an ignition of the process gas to form the plasma.

In addition, in some embodiments, providing the negative or zero voltage to the substrate support may offset an existing positive charge on the substrate. For example, the inventors has observed that a positive charge on the substrate can result from the flow of coolant through the substrate support (as described above with respect to FIG. 1). The positive charge on the substrate may undesirably attract particles. By applying the negative or zero voltage to offset the positive charge on the substrate, particle formation on the substrate may be reduced or eliminated. In some embodiments, the offset of an existing positive charge may be facilitated by grounding the substrate support. In such embodiments, the substrate support may be grounded mechanically, for example, by coupling a conductive material from the substrate support to the process chamber. Alternatively, or in addition, in some embodiments a resistor or inductor may be coupled between the substrate support and the ground to facilitate a slow discharge of energy.

Next, at 208 a source RF power may be coupled to a process chamber anode coupled to the process chamber to ignite the process gas to form a plasma. The source RF power may be provided by a plasma power source 112 coupled to an anode (induction coils 130) via a match network 114, as described above with respect to FIG. 1. The source RF power may be provided at any suitable magnitude and frequency required to ignite the particular process gas provided to the process chamber to form the plasma. For example, in some embodiments the source RF power may be provided at about 250 to about 450 W, at a frequency of about 13.56 MHz.

Following the ignition of the process gas to form a plasma at 208 the photomask can proceed for processing at 210. The photomask may be processed as required for a particular application. For example, in some embodiments, the photomask may be etched using the plasma formed at 210 to form features therein. In some embodiments, following the ignition of the process gas to form the plasma, the DC power may be adjusted to modify a local plasma density around the photomask, thus allowing for control over the subsequent photomask processing. In some embodiments, for example where the substrate support is mechanically grounded as described above, the mechanical ground may be removed, allowing the substrate support (and therefore the substrate) to become positively charged, thus attracting energized ions in the plasma, causing the ions to bombard the substrate, thereby facilitating the etch.

Alternatively, or in addition, in some embodiments, following the formation of the plasma a bias power may be applied to the substrate support to bias the substrate, thus attracting the energized ions in the plasma, causing the ions to bombard the substrate, thereby facilitating the etch.

Although the above embodiments are described with respect to a method for processing a photomask comprising a phase shift layer (e.g., the MoSi layer), the inventors have observed that the inventive methods may be used in any plasma process where ignition of a plasma is difficult due to a high amount of energy required to ionize a process gas and where such high energy may risk damaging a substrate disposed in the process chamber. For example, in some embodiments, the inventive methods may be used for etch processes, deposition processes, or the like.

Thus, methods for processing photomasks have been provided that may advantageously provide consistent plasma ignition during photomask processing. The inventive methods reduce or eliminate damage to the photomask resulting from the failure of the plasma to ignite.

While the foregoing is directed to embodiments of the present invention, other and further embodiments of the invention may be devised without departing from the basic scope thereof.

1. A method of processing a photomask, comprising:
providing a photomask to a substrate support within a process chamber;
providing a process gas to the process chamber having the photomask disposed therein;
providing a negative or zero voltage to a substrate support cathode having the photomask disposed thereon;
providing a source RF power to an anode coupled to the process chamber to ignite the process gas to form a plasma; and
processing the photomask.

2. The method of claim 1, further comprising:
evacuating the process chamber to a desired pressure prior to providing the process gas to the process chamber.

3. The method of claim 2, wherein the process chamber is maintained at a pressure of about 2 to about 8 mTorr.

4. The method of claim 1, wherein the process gas is provided at a total flow rate of about 150 to about 300 sccm.

5. The method of claim 1, wherein the process gas comprises a dilutant gas and an ignition gas.

6. The method of claim 5, wherein the ignition gas is provided at a flow rate of about 5 to about 10 sccm.

7. The method of claim 5, wherein the dilutant gas is provided at a flow rate of about 150 to about 300 sccm.

8. The method of claim 5, wherein the dilutant gas is at least one of helium (He), nitrogen (N₂), or argon (Ar).

9. The method of claim 5, wherein the ignition gas is at least one of sulfur hexafluoride (SF₆), argon (Ar), or nitrogen (N₂).

10. The method of claim 5, wherein the flow rate ratio of dilutant gas to ignition gas is about 15:1 to about 60:1.

11. The method of claim 1, wherein providing the negative or zero voltage to the substrate support cathode comprises providing about 0 to about −3000 volts via a DC voltage module.

12. The method of claim 1, wherein providing the negative or zero voltage to the substrate support cathode comprises providing zero voltage by coupling the substrate support cathode to a ground.

13. The method of claim 12, further comprising:
removing the ground after igniting the process gas to form the plasma.

14. The method of claim 1, wherein providing the source RF power comprises providing the source power at about 250 to about 450 W.

15. The method of claim 14, wherein providing the source RF power further comprises proving the source power at a frequency of about 13.56 MHz.

16. The method of claim 1, further comprising:
after igniting the process gas to form the plasma, adjusting the source power to control a plasma density.

17. The method of claim 1, wherein the photomask comprises at least one of molybdenum silicide (MoSi), or molybdenum silicon oxynitride (MoSiON).

18. The method of claim 1, wherein the substrate support comprises one or more zones, wherein the one or more zones may each be configured to be electrically hot or grounded.

19. The method of claim 1, wherein the negative or zero voltage is a negative voltage selectively applied to a portion of the substrate support cathode to adjust a local plasma density above the substrate support cathode.

20. The method of claim 1, further comprising:
applying a bias power to the substrate support pedestal while processing the photomask.
